(19) United States
(12) Patent Application Publication
(10) Pub. No.: US 2017/0179041 A1
(43) Pub. Date: Jun. 22, 2017

(54) SEMICONDUCTOR PACKAGE WITH TRENCHED MOLDING-BASED ELECTROMAGNETIC INTERFERENCE SHIELDING

(71) Applicant: Intel Corporation, Santa Clara, CA (US)

(72) Inventors: Rajendra C. Dias, Phoenix, AZ (US); Eric J. Li, Chandler, AZ (US); Joshua D. Heppner, Chandler, AZ (US)

(21) Appl. No.: 14/978,897

(22) Filed: Dec. 22, 2015

(51) Int. Cl. H01L 23/552; H01L 23/29; H01L 23/528; H01L 21/56; H01L 21/78; H01L 21/311; H01L 21/3105; H01L 23/31; H01L 21/768

(52) U.S. Cl. CPC H01L 23/552; H01L 23/3157; H01L 23/293; H01L 23/528; H01L 21/76877; H01L 21/78; H01L 21/31111; H01L 21/31116; H01L 21/3105; H01L 21/565

(57) ABSTRACT

Semiconductor packages with electromagnetic interference (EMI) shielding and a method of manufacture therefor is disclosed. The semiconductor packages may house single electronic component or may be a system in a package (SiP) implementation. The EMI shielding may be provided on top of and along the periphery of the semiconductor package. The EMI shielding on the periphery may be formed of cured conductive ink or cured conductive paste disposed on sidewalls of molding that encapsulates the electronic component(s) provided on the semiconductor package. The vertical portions of the EMI shielding, including EMI shielding on the periphery may be formed by filling conductive ink in trenches formed in-situ with curing the molding. The top portion of the EMI shielding and the may additionally be cured conductive ink.

### TECHNICAL FIELD

This disclosure generally relates to semiconductor packages, and more particularly to semiconductor packages with trenched molding-based electromagnetic shielding.

### BACKGROUND

Integrated circuit(s) and other electronic devices may be packaged on a semiconductor package. The semiconductor package may be integrated onto an electronic system, such as a consumer electronic system. The integrated circuit(s) and/or electronic devices provided on the semiconductor package may interfere with each other or with other electronic components of a system in which the semiconductor package is integrated.

### BRIEF DESCRIPTION OF THE FIGURES

Reference will now be made to the accompanying drawings, which are not necessarily drawn to scale, and wherein:

FIGS. 1A-1H depict simplified cross-sectional schematic diagrams of an example semiconductor package with a trenched molding-based electromagnetic interference (EMI) shield and fabrication process, in accordance with example embodiments of the disclosure.

FIGS. 2A-2D depict simplified cross-sectional schematic diagrams illustrating various semiconductor packages with trenched molding-based EMI shielding, in accordance with example embodiments of the disclosure.

FIGS. 3A and 3B depict simplified cross-sectional schematic diagrams illustrating semiconductor packages with multiple dies provided therein with trenched molding-based EMI shielding, in accordance with example embodiments of the disclosure.

FIGS. 4A and 4B depict simplified cross-sectional schematic diagrams illustrating semiconductor packages having any variety of electrical and mechanical coupling between the die and the semiconductor package having a trenched molding-based EMI shield, in accordance with example embodiments of the disclosure.

FIG. 5 depicts a simplified cross-sectional schematic diagram illustrating a system in a package (SiP) with trenched molding-based EMI shielding around one or more electronic components, in accordance with example embodiments of the disclosure.

FIG. 6 depicts a simplified schematic diagram illustrating a chase for curing molding epoxy with inserts disposed thereon and a resulting trenching of molding on the surface of a system in a package, where the molding epoxy was cured with the chase with the inserts, in accordance with example embodiments of the disclosure.

FIG. 7 depicts a simplified cross-sectional schematic diagram of a chase with inserts disposed thereon, in accordance with example embodiments of the disclosure.

FIG. 8 depicts a flow diagram illustrating an example method for fabricating the semiconductor packages with trenched molding-based EMI structures of FIGS. 1-5, in accordance with example embodiments of the disclosure.

### DETAILED DESCRIPTION OF EMBODIMENTS OF THE DISCLOSURE

Embodiments of the disclosure are described more fully hereinafter with reference to the accompanying drawings, in which example embodiments of the disclosure are shown. This disclosure may, however, be embodied in many different forms and should not be construed as limited to the example embodiments set forth herein; rather, these embodiments are provided so that this disclosure will be thorough and complete, and will fully convey the scope of the disclosure to those skilled in the art. Like numbers refer to like, but not necessarily the same or identical, elements throughout.

The following embodiments are described in sufficient detail to enable at least those skilled in the art to understand and use the disclosure. It is to be understood that other embodiments would be evident based on the present disclosure and that process, mechanical, materials, dimensional, process equipment, and parametric changes may be made without departing from the scope of the present disclosure.

In the following description, numerous specific details are given to provide a thorough understanding of various embodiments of the disclosure. However, it will be apparent that the disclosure may be practiced without these specific details. In order to avoid obscuring the present disclosure, some well-known system configurations and process steps may not be disclosed in full detail. Likewise, the drawings showing embodiments of the disclosure are semi-diagrammatic and not to scale and, particularly, some of the dimensions are for the clarity of presentation and may be exaggerated in the drawings. In addition, where multiple embodiments are disclosed and described as having some features in common, for clarity and ease of illustration, description, and comprehension thereof, similar and like features will ordinarily be described with like reference numerals even if the features are not identical.

The term “horizontal” as used herein may be defined as a direction parallel to a plane or surface (e.g., surface of a substrate), regardless of its orientation. The term “vertical” as used herein may refer to a direction orthogonal to the horizontal direction as just described. Terms, such as “on,” “above,” “below,” “bottom,” “top,” “side” (as in “sidewall”), “higher,” “lower,” “upper,” “over,” and “under,” may be referenced with respect to the horizontal plane. The term “processing” as used herein includes deposition of material or photoresist, patterning, exposure, development, etching, cleaning, ablating, polishing, and/or the removal of the material or photoresist as required in forming a described structure.

Embodiments of the disclosure may provide a semiconductor package and a method for fabrication of the semiconductor package. In example embodiments, the semiconductor package may have one or more electromagnetic interference (EMI) shielding structures, as described herein. These semiconductor packages with the EMI shielding structures may be fabricated using the methods of molding trench formation in-situ with curing molding epoxy, as disclosed herein. In example embodiments, curing the molding epoxy may include using a mold chase with protrusions thereon that may indent the molding epoxy during the curing process and result in a trench formation in the molding after the cure. The protrusions may, in example embodiments, be inserts of any suitable material provided on the chase. The length of the protrusions may be approximately the thickness of the molding compound such that trenches formed in the molding extend substantially the full thickness of the molding. The molding formation process may include depositing a molding compound (e.g., thermosetting epoxy) and then thermally curing the same while applying contact and/or pressure to the top of the molding compound during the curing (e.g., cross-linking, hardening, etc.). The molding compound curing, according to embodiments of the disclosure, may include aligning the chase over the package substrate such that the protrusions align with features on the surface of the package substrate during the application of the chase over the surface of the uncured molding compound. The alignment of the chase over the surface of the molding compound may involve any suitable alignment mechanism, including, for example, forming alignment marks on the surface of the packaging substrate and aligning to those marks.

The chase with the protrusions, as aligned and applied to the surface of the molding compound, may be heated, such as heated to a temperature at which the molding compound may be driven to curing. It will be appreciated that the positions on the surface of the molding compound where the protrusions of the chase line up, the molding compound may be squeezed, or otherwise displaced, during the curing process. Thus, at these positions on the package substrates corresponding to the protrusions on the chase, trenches may be formed in the molding compound during the curing of the molding. As a result of the alignment of the chase over the packaging substrate, the trenches may be formed overlying grounded traces on the surface of the packaging substrate.

In example embodiments, the semiconductor package structures may include a package substrate. In some cases, the package substrate may be an organic structure. In other cases, the package substrate may be inorganic (e.g., ceramic, glass, etc.). The package substrate may, in example embodiments, include a core layer with one or more interconnect layers built up on one or both sides of the core layer. One or more electronic components, including at least one integrated circuit die, may be electrically and mechanically coupled to the package substrate via any suitable mechanism, such as metal pillars (e.g., copper pillars), flip chip bumps, solder bumps, any type of low-lead or lead-free solder bumps, tin-copper bumps, wire bonds, wedge bonds, controlled collapse chip connects (C4), anisotropic conductive film (ACF), nonconductive film (NCF), combinations thereof, or the like. Semiconductor package-to-board level interconnects may be provided on one or both sides of the package substrate. In example embodiments, the semiconductor package-to-board level interconnects may be ball grid array (BGA) connections.

The semiconductor package may have a ground layer provided on the surface of the semiconductor package, such as on the top interconnect layer of the semiconductor package. In other cases, the semiconductor package may have a ground plane formed in a layer that is within the package substrate, such as on the package core and/or a build-up layer that is not on the surface of the package substrate. Molding, to mechanically protect the electronic components, may be formed on top of the one or more electronic components on a surface of the semiconductor package. Semiconductor package-to-board level interconnects may be provided on one or both sides of the package substrate.

According to example embodiments, there may be a semiconductor package having trenches within the molding that are filled with conductive material. The trenches may be formed in-situ during the molding epoxy cure. According to the same or different embodiments, the semiconductor package may further have conductive material on at least a portion of a top surface of the molding material. The conductive material at the top of the molding material and within the trenches may be electrically coupled to each other. In further example embodiments, the conductive material at the top of the molding material and within the trenches of the molding material may be shorted to a ground plane of the semiconductor package. Alternatively, the conductive material at the top of the molding material and within the trenches of the molding material may be shorted to a power plane of the semiconductor package, or otherwise pinned to any other suitable direct current (DC) voltage.

In example embodiments, the semiconductor package may have sidewalls fabricated of cured conductive ink and/or cured conductive paste. In example embodiments, the conductive ink and/or paste may be both provided within channels formed within the molding, as well as on the sidewalls of the semiconductor package. Thus, individual or groups of integrated circuits and/or other electronic components may be surrounded by a trench with conductive material disposed therein, such as to isolate the individual or group of integrated circuits and/or other electronic components from other components in a system in package (SiP) implementation.

The conductive material on top of the semiconductor package may be formed by puddling up the conductive ink used to fill the trenches formed while curing the molding epoxy. In these example embodiments, the top conductive layer disposed on the molding top surface may also be formed with cured conductive ink and/or cured conductive paste. In these example embodiments, the top surface conductive material may be substantially the same as the conductive material disposed in trenches of the molding and/or the sidewalls of singulated semiconductor packages. It will be appreciated that multiple semiconductor packages may be formed on a single semiconductor package substrate (e.g., core with build-up layers).

Alternatively, the conductive material on top of the semiconductor package may be disposed by laminating a metal sheet (e.g., copper laminate, aluminum laminate, etc.) on top of the semiconductor package molding. In example embodiments, the lamination may be provided on the molding surface with an epoxy between the laminate metal and the molding top surface. In still further alternative embodiments, conductive material may be deposited on top of the semiconductor package by physical vapor deposition (PVD).

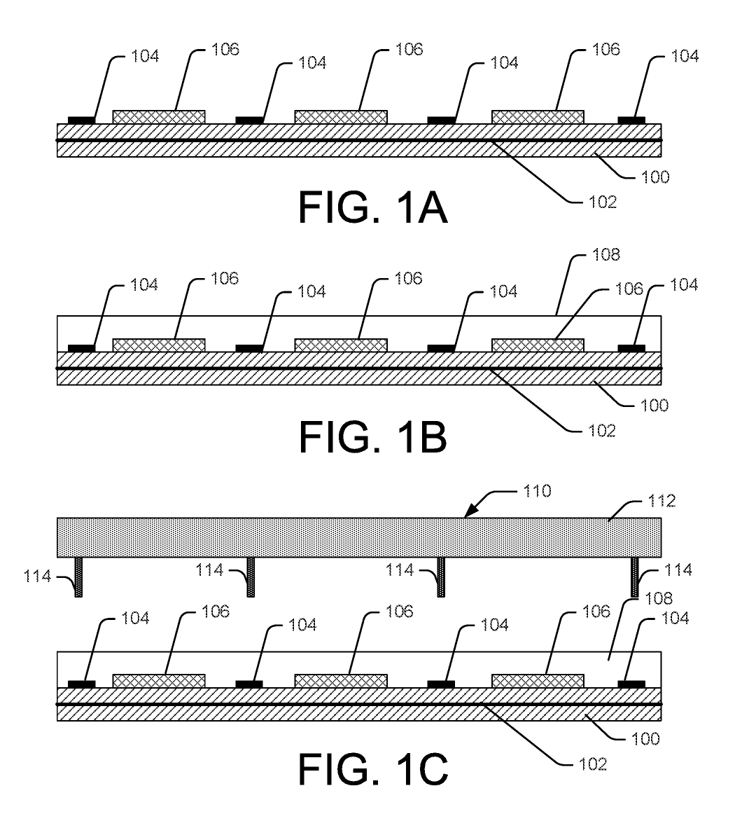

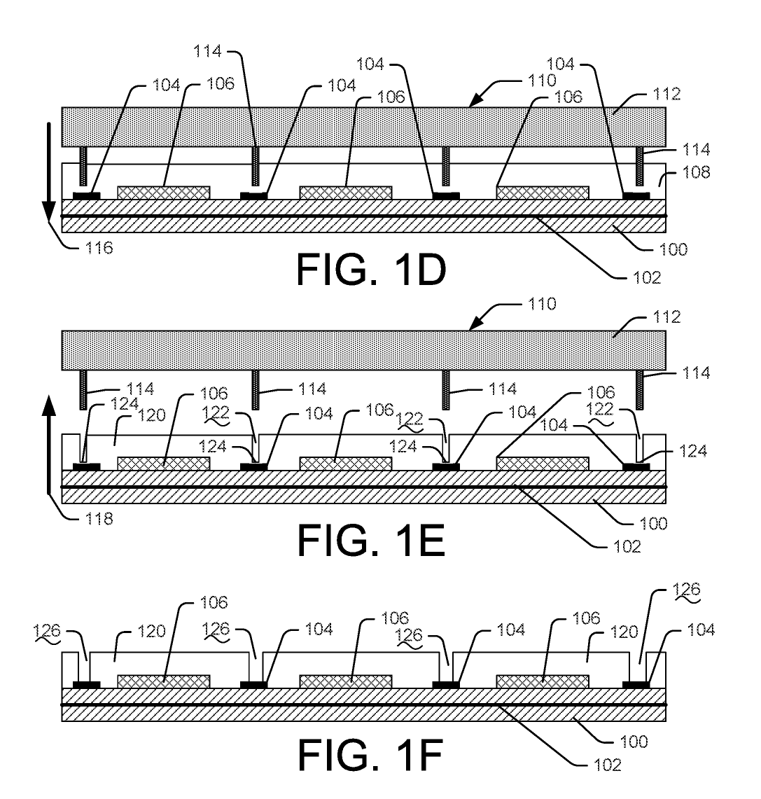

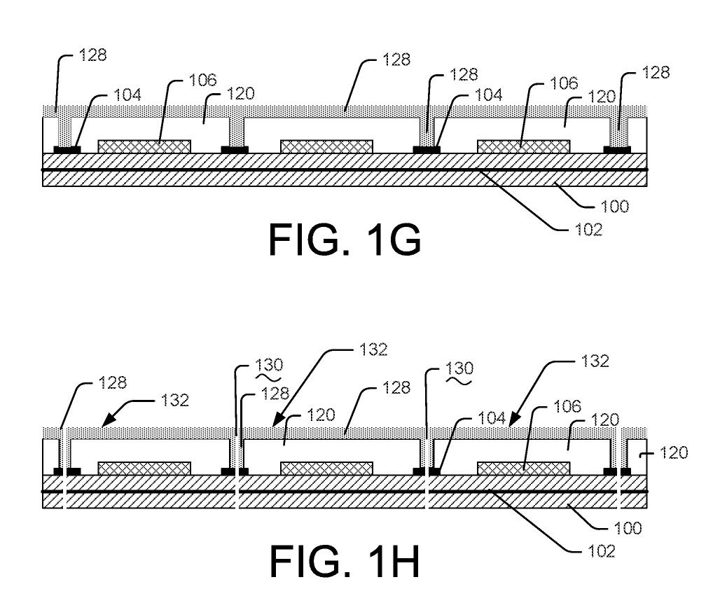

FIGS. 1A-1H depict simplified cross-sectional schematic diagrams of an example semiconductor package with a trenched molding-based electromagnetic interference (EMI) shield and fabrication process, in accordance with example embodiments of the disclosure.

The processes, as depicted herein, may be implemented to concurrently or nearly concurrently fabricate a plurality of semiconductor packages with EMI shielding. The semiconductor package may be fabricated with any variety of processes or sequences thereof. Although a particular fabrication sequence is shown here with fabrication of various structures and/or features, both final and/or temporary, any variations for fabricating similar features may be implemented in accordance with example embodiments of the disclosure. Further still, there may be additional and/or fewer features than the features disclosed herein for the fabrication of the semiconductor package, in accordance with example embodiments of the disclosure. Although the cross-sections as depicted here show a particular number of semiconductor packages fabricated concurrently on a package substrate panel, it will be appreciated that there may be any number of semiconductor packages that are fabricated concurrently or nearly concurrently on a particular package substrate panel. Additionally, although an example embodiment of the sequence of processes for fabricating a semiconductor package with EMI shielding is depicted, it will be appreciated that there may be any number of package substrate panels that may be processed concurrently and/or near concurrently through any of the processes depicted herein. For example, some processes may be batch processes where a particular unit (e.g., package substrate panel) may be processed along with another of that unit. In other cases, unit processes may be performed in a sequential manner on work-in-progress (WIP).

In FIG. 1A, a schematic cross-section of an example semiconductor package substrate 100 is depicted with a ground plane 102 fabricated within the package substrate 100 and ground contacts 104 and electronic components 106 disposed thereon, in accordance with example embodiments of the disclosure. The semiconductor package substrate 100 may be of any suitable size and/or shape. For example, the semiconductor package substrate 100, in example embodiments, may be a rectangular panel. In example embodiments, the semiconductor package substrate 100 may be fabricated of any suitable material, including polymer material, ceramic material, plastics, composite materials, glass, epoxy laminates of fiberglass sheets, FR-4 materials, FR-5 materials, combinations thereof, or the like. The substrate may have a core layer and any number of interconnect build-up layers on either side of the core layer. The core and/or the interconnect build-up layers may be any variety of the aforementioned materials and, in some example embodiments, may not be constructed of the same material types.

It will be appreciated that the build-up layers may be fabricated in any suitable fashion. For example, a first layer of build-up interconnect may include providing a package substrate core, with or without through holes formed therein. Dielectric laminate material may be laminated on the semiconductor substrate core material. Vias and/or trenches may be patterned in the build-up layer using any suitable mechanism, including photolithography, plasma etch, laser ablation, wet etch, combinations thereof, or the like. The vias and trenches may be defined by vertical and horizontal metal traces, respectively within the build-up layer. The vias and trenches may then be filled with metal, such as by electroless metal plating, electrolytic metal plating, physical vapor deposition, combinations thereof, or the like. Excess metal may be removed by any suitable mechanism, such as etch, clean, polish, and/or chemical mechanical polish (CMP), combinations thereof, or the like. Subsequent build-up layers (e.g., higher levels of build-up layers) on either side of the core may be formed by the same aforementioned processes.

The ground plane 102 may be, in example embodiments, a build-up layer (e.g., a build-up layer with interconnects) within the semiconductor package substrate 100. When the final package substrate with the EMI shielding is in operation, the ground plane may be shorted to ground, such as on a printed circuit board (PCB) on which the final package substrate with EMI shielding is disposed. The ground plane may be electrically connected, in example embodiments, to one or more surface ground pads 104. The surface ground pads 104 may be one or more pads and/or interconnect traces (e.g., surface wiring traces) on the top surface of the semiconductor package substrate 100.

The semiconductor package substrate 100 may have one or more electronic components or devices 106 disposed thereon. Although for illustrative purposes, only one electronic component 106 per semiconductor package substrate 100 is depicted in FIGS. 1A-1H, it will be appreciated that there may be any suitable number of electronic components 106 disposed in each semiconductor package with EMI shielding, in accordance with example embodiments of the disclosure. The electronic components 106 may be any suitable electronic components 106 including, but not limited to, integrated circuits, surface mount devices, active devices, passive devices, diodes, transistors, connectors, resistors, inductors, capacitors, microelectromechanical systems (MEMSs), combinations thereof, or the like. The electronic components 106 may be electrically and mechanically coupled to the semiconductor package substrate 100 via any suitable mechanism, such as metal pillars (e.g., copper pillars), flip chip bumps, solder bumps, any type of low-lead or lead-free solder bumps, tin-copper bumps, wire bonds, wedge bonds, controlled collapse chip connects (C4), anisotropic conductive film (ACF), nonconductive film (NCF), combinations thereof, or the like.

In FIG. 1B, a schematic cross-section of the example semiconductor package substrate 100 of FIG. 1A is depicted with molding compound 108 provided thereon, in accordance with example embodiments of the disclosure. The molding compound 108 may be disposed on the top surface of the package substrate 100 and may encapsulate the surface ground pads 104 and/or the electronic components 106 disposed on the surface of the semiconductor package substrate 100. The molding compound 108 may be any suitable molding material. For example, the molding compound 108 may be a liquid dispensed thermosetting epoxy resin molding compound. The molding compound may be deposited on the surface of the semiconductor package substrate 100 using any suitable mechanism including, but not limited to, liquid dispense, spin coating, spray coating, combinations thereof, or the like.

FIG. 1C is a schematic cross-section of the example semiconductor package substrate 100 of FIG. 1B with molding compound 108 that is ready to be cured using chase 110 with a body 112 and protrusions 114 therefrom, in accordance with example embodiments of the disclosure. This setup may be in a curing environment in which molding compound is cured (e.g., cross-linked, hardened, etc.). In example embodiments, the chase 110 may be aligned with features on the surface of the package substrate 100, such as one or more alignment marks. In these example embodiments, aligning the chase 110 may result in aligning the protrusions 114 on the chase to corresponding locations on the surface of the package substrate 100. These may be locations on the package substrate where a trench may be desired. Such trenches may be desired for the purposes of filling with conductive material to form electromagnetic interference (EMI) shielding, in accordance with example embodiments of the disclosure. In example embodiments, the chase may be aligned over the molding compound 108 such that the protrusions 114 may be aligned with surface ground pads 104. Indeed, such an alignment may result in formation of trenches overlying the surface ground pads 104.

FIG. 1D is a schematic cross-section of the example semiconductor package substrate 100 of FIG. 1C with the chase 110 moved 116 into and onto the molding compound 108, in accordance with example embodiments of the disclosure. In example embodiments, the chase 110, with the relatively flat surface 112 and with the protrusions 114, may be pressed on top of the liquid molding compound 108 disposed on top of the semiconductor package substrate 100 with the chase 110 itself heated. The molding compound 108 on the top surface of the semiconductor package substrate 100, may be cured while pressure is applied thereon by a chase 110. In example embodiments, the chase 110 may be aligned such that the protrusions 114 are pressed into locations where the it is desired to displace the molding compound 108 on the surface of the semiconductor substrate 100. In some example embodiments, the protrusions 114 may be aligned with one or more of the surface ground pads 104, such that molding compound 108 may be squeezed, or otherwise displaced, over those one or more surface ground pads 104 when the chase 110 is applied over the molding compound 108.

FIG. 1E is a schematic cross-section of the example semiconductor package substrate 100 of FIG. 1D with the chase 110 moved 118 away from molding 120, in accordance with example embodiments of the disclosure. Upon curing (e.g., cross-linking), while in contact with chase 110, the deposited molding compound 108 may harden and form molding 120 to adhere to the semiconductor package substrate 100 and encapsulate the electronic components 106. In example embodiments, the molding 120 may have fillers and/or other materials therein to preferentially control the coefficient of thermal expansion (CTE), reduce stresses, impart flame retardant properties, promote adhesion, and/or reduce moisture uptake in the molding 120. The molding 120, in example embodiments, may be any suitable thickness. For example, the molding 108 may be approximately 1 millimeter (mm) thick. In other cases, the molding 108 may be approximately in the range between about 200 microns (μm) and 800 μm thick. In yet other cases, the molding 108 may be approximately in the range between about 1 mm and 2 mm thick.

In accordance with example embodiments, the molding 120 may have trenches 122 formed therein. These trenches 122 may be formed in locations of the molding 120 that correspond to the protrusions 114 of the chase 110. In some example embodiments, the trenches 122 may overlie the surface ground pads 104 on the surface of the package substrate 100. These trenches 120, in example embodiments, may not open cleanly to the surface of the underlying surface ground pads. Thus, there may be residue 124 at the bottom of the trenches 122. In example embodiments, the residue 124 may be a relatively small amount of molding left behind at the bottom of the trench 122.

In FIG. 1F, a schematic cross-section of the example semiconductor package substrate 100 of FIG. 1E is depicted with the residue 124 removed, in accordance with example embodiments of the disclosure. The residue removal process may involve any variety of etching and/or cleaning processes to form trenches 126. The trenches 126 may, in example embodiments, be wider than trenches 124. Furthermore, in example embodiments, the trenches 126 may not have residue at the bottom thereof, and may open to the underlying surface ground pads 104. The residue 124 may be removed by any suitable etching and/or cleaning process including, laser ablation, wet etch, dry etch, plasma etch, wet clean, sonic clean, combinations thereof, or the like. In some example embodiments, the type and/or sequence of clean and/or etch process(es) may be selected such that the lateral etch is relatively minimized compared to the vertical etch. In other words, the etch and/or clean process may be optimized from a more directional removal of residue 124 that does not widen the trenches 126 significantly compared to trenches 122.

The trenches 126 may be formed in locations where vertical portions of the EMI shielding is to be formed, optionally including the semiconductor package sidewalls, on the final semiconductor packaging with EMI shielding. In example embodiments, the trenches 126 may be formed such that the bottom of the trenches 126 open up to the surface ground pads and/or traces 104. In some example embodiments, each non-contiguous section of the trenches 126 may be opened to at least one surface ground pad 104, so that all sections of the final EMI shielding may be grounded. In some example embodiments, the mechanism (e.g., laser ablation, etching, etc.) used for removing the residue 124 may be selective in removing the molding material relative to the material (e.g., copper, aluminum, etc.) of the surface ground pad 104.

The width of the trenches 126 may be any suitable width. In example embodiments, the trenches 126 may be approximately the kerf width of a saw blade that is eventually used to saw and/or singulate the semiconductor package substrate 100 to form each of the semiconductor packages with trenched molding-based EMI shielding, in accordance with example embodiments of the disclosure. In other example embodiments, the trenches 126 may be wider than the kerf of the saw that is eventually used to singulate the individual semiconductor packages. In some cases, the trenches 126 may be approximately 500 μm in width. In other cases, the trench 126 widths may be approximately in the range of about 100 μm to 500 μm.

In FIG. 1G, a schematic cross-section of the example semiconductor package substrate 100 with molding 120 with filled trenches is depicted, in accordance with example embodiments of the disclosure. The trenches may be filled with any suitable conductive material, such as conductive ink 128 and/or conductive paste. The conductive ink 128 may further puddle up on the top surface of the molding 120 to form a top portion of the EMI shielding. The conductive ink 128, such as conductive paste, may be dispensed on the top surface of the molding 120 and may subsequently fill the trenches 126. The conductive ink 128 may be disposed on the molding 120 surface by spin deposition, spray deposition, screen printing, squeegee process, and/or any other suitable deposition process. In example embodiments, the conductive ink 128 may wet the molding 120 and, therefore, may fill the trenches 126 driven by Van der Waals forces and/or capillary action. In the same or other example embodiments, the conductive ink 128 may be forced into the trenches 126 by mechanical force, such as by a squeegee process. In yet other example embodiments, the conductive ink 128 may be preferentially deposited using a screen printing process, such as by aligning a patterned screen on top of the surface of the molding 120.

The conductive ink 128 may be an epoxy material with metal nanoparticles or microparticles suspended therein. In example embodiments, the conductive ink 128 may have silver (Ag) nanoparticles suspended therein. In other example embodiments, the conductive ink 128 may have nanoparticles of copper, tin, iron, gold, combinations thereof, or the like, suspended therein. In some embodiments, the conductive ink 128 may have suspended therein non-metallic electrically conductive particles. In addition to having conductive materials in the conductive ink 128, there may further be other chemical agents to tune the physical, electrical, and/or processing properties of the conductive ink 128. In example embodiments, the conductive ink 128 may have solvents that may allow the conductive ink 128 to have a viscosity that may be relatively preferential for trench filling, while providing a relatively quick increase in viscosity and/or tackiness for staging in the trenches 126. In same or other example embodiments, the conductive ink 128 may have reducing agents to prevent or reduce oxidation of metal particles that may be suspended in the conductive ink 128. Further still, the conductive ink 128 may contain filler particles (e.g., carbon fibers, silica particles, ceramics, etc.) in proportions that provide the conductive ink 128 with desirable properties, such as a preferred range of viscosity, a preferred range of tackiness, a preferred range of hydrophobicity (e.g., surface wetting), a preferred range of particle suspension properties, a preferred range of cure temperatures, combinations thereof, or the like.

In some example embodiments, the conductive ink 128 may be provided on the molding 120 by first providing a less viscous conductive ink that preferentially gap fills within the trenches 126 and then provide a more viscous conductive ink that puddles on top of the molding 120 to provide the top portion of EMI shielding. In some example embodiments, the viscosity of the conductive ink 128 may be varied by the amount of solvent(s) mixed in the conductive ink 128. In alternative embodiments, instead of providing conductive ink 128 over the top surface of the molding 120, a metal sheet may be provided, such as by lamination, or other mechanisms of metal deposition may be employed, such as PVD.

FIG. 1H depicts a schematic cross-section of the package substrate 100 of FIG. 1G that has been singulated to form individual semiconductor packages with EMI shielding 132, in accordance with example embodiments of the disclosure. The individual semiconductor packages with trenched molding-based EMI shielding 132, as fabricated on the semiconductor package substrate 100, may be singulated by cutting through the edges of each individual semiconductor package to provide a separation 130 therebetween. The singulation may be performed using laser ablation, saw, or any other suitable mechanism. In example embodiments where laser ablation is used, the ablation width between the adjacent semiconductor packages 132 may be less than the width of the conductive ink 128 filled trenches between the adjacent semiconductor packages 132. In other example embodiments, where a saw cut is implemented, the kerf width between the adjacent semiconductor packages 132 may be less than the width of the conductive ink 128 filled trenches between the adjacent semiconductor packages. In these example embodiments, where the singulation width of the cut between the semiconductor package 132 is less than the width of the conductive ink filled trenches, the singulated semiconductor package 132 will have conductive ink (e.g., cured conductive ink) on its sidewall (e.g., along its perimeter). This conductive ink sidewall may be grounded (e.g., electrically connected to the surface ground pads 104 that are further connected to ground plane layer 102) to form the sidewall portion of the EMI shielding of the semiconductor package. The top of the EMI shielding may be formed by the conductive ink 128 on top of the semiconductor package 132.

It will be appreciated that the processes as described in conjunction with FIGS. 1A-1H may form an electromagnetic shield surrounding one or more electronic components 106 disposed on the surface of a semiconductor package. The EMI shielding may have a top portion and sidewall that encapsulates the electronic components 106. The sidewalls of the semiconductor package may have EMI shielding in the form of conductive ink sidewalls along the periphery and from top to bottom of the semiconductor package 132. Additionally, there may be vertical portions (e.g., conductive ink filled trenches) that are not along the periphery of these singulated semiconductor packages with EMI shielding. In these cases, in an SiP configuration, some electronic components 106 on the semiconductor package may be shielded from other electronic components 106 on the semiconductor package 132. For example, an amplifier of a relatively high frequency signal may be isolated from other electronic components on the semiconductor package using the vertical portions of the EMI shielding to prevent the amplifier from injecting electromagnetic noise into other components of the SiP. In alternative embodiments, it will be appreciated that laminate metal or PVD deposited metal may be used to form the top and/or the sidewalls of the EMI shielding.

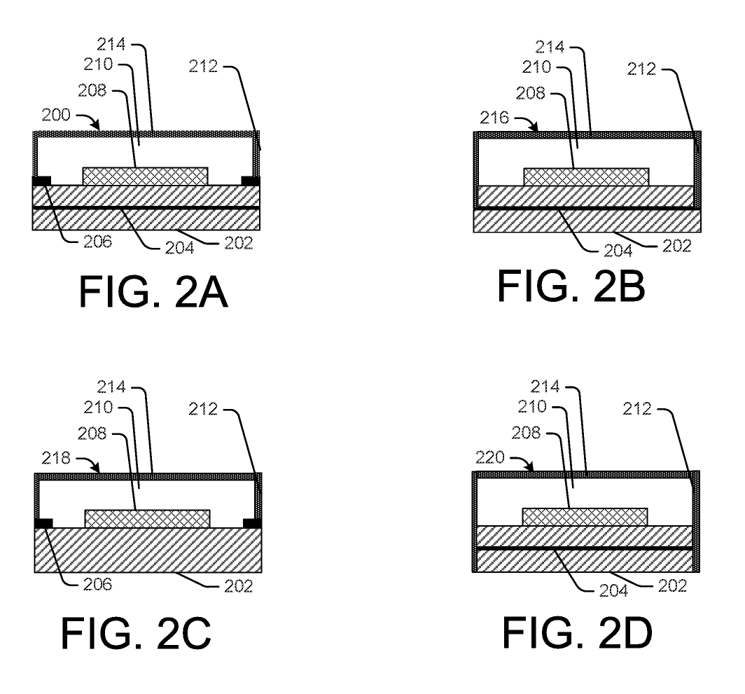

FIGS. 2A-2D depict simplified cross-sectional schematic diagrams illustrating various semiconductor packages with trenched molding-based EMI shielding 200, 216, 218, 220, in accordance with example embodiments of the disclosure. While FIGS. 2A-2D describe various embodiments of the semiconductor package with trenched molding-based EMI shielding 200, 216, 218, 220, in accordance with example embodiments of the disclosure, it will be appreciated that these embodiments are examples and the disclosure is not, in any way, limited by the variations described in FIGS. 2A-2D.

FIG. 2A is a simplified cross-sectional schematic diagram illustrating a semiconductor package 200 fabricated according to the processes of FIGS. 1A-1G, in accordance with example embodiments of the disclosure. The semiconductor package 200 includes a package substrate 202, a ground plane 204, surface ground pads or traces 206, an electronic component 208, molding 210 encapsulating the electronic component 208, a conductive ink-based conductive sidewall 216, and a conductive ink-based top portion overlying the molding 210. The conductive sidewall 216 contacting the surface ground pads 206, and further in contact with the conductive top 214 may provide EMI shielding for the package 200. According to example embodiments, the conductive sidewalls 216 may be formed by forming trenches during the molding cure process using protrusions on a chase used for curing the molding 210. These trenches may next be cleaned and/or opened up to the underlying surface ground pads 206. Next, the trenches may be filled with conductive ink with conductive ink puddled up over the surface of the molding 210. Alternatively, a gap filling conductive ink process may be performed, followed by a second top conductive ink deposition process. In this example embodiment, a less viscous conductive ink may be utilized in the conductive ink gap filling process for relatively good gap filling performance, and a relatively more viscous conductive ink may be used in the top conductor deposition process to enhance tackiness.

FIG. 2B is a simplified cross-sectional schematic diagram illustrating a semiconductor package 216 with conductive ink-based conductive sidewalls 212 that extend down to the ground plane 204 and a conductive ink-based top portion 214 of the EMI shielding, in accordance with example embodiments of the disclosure. In this example embodiment, there may be relatively fewer, compared to semiconductor package 200 of FIG. 2A, or no surface ground pad connections of the conductive sidewall 220. In this example embodiment, the trench formation may be such that the trench is formed into the package substrate 202 until the trench lands on the ground plane 204 layer. In this case, the semiconductor package 216 design rules may be such that the interconnect layers overlying the regions where the conductive sidewall 220 extends down to the ground plane 204 may have exclusion regions without circuitry to allow the conductive sidewalls 212 to extend into the package substrate 202. In this embodiment of the semiconductor package with trenched molding-based EMI shielding 216, the trenches for forming the conductive sidewalls 238 of the EMI shielding may be formed such that they extend through the molding, as well as build-up layers on top of the package substrate 202.

FIG. 2C is a simplified cross-sectional schematic diagram illustrating a semiconductor package 218 with conductive ink-based conductive sidewalls 212 where the surface ground pads or traces 206 are on the surface of the package substrate 202, in accordance with example embodiments of the disclosure. In this embodiment, there may not be a ground plane within the interconnect layers of the package substrate. The conductive sidewalls 212, formed of cured conductive ink may contact the ground pads 206 on the surface of the package substrate 202 to form the EMI shield along with the top conductor 214. In example embodiments, the top portion 214 of the EMI shielding may be fabricated by the conductive ink or conductive paste by having conductive ink puddle over the top of the molding 210 when gap filling the trenches formed in the molding 210. Alternatively, a gap filling conductive ink process may be performed, followed by a second top conductive ink deposition process. In this example embodiment, a less viscous conductive ink may be utilized in the conductive ink gap filling process for relatively good gap filling performance, and a relatively more viscous conductive ink may be used in the top conductor deposition process to enhance tackiness.

FIG. 2D is a simplified cross-sectional schematic diagram illustrating a semiconductor package 220 with conductive ink-based conductive sidewalls 212 and a conductive ink-based top portion 214 of the EMI shielding, in accordance with example embodiments of the disclosure. In example embodiments, the top portion 214 of the EMI shielding may be fabricated by the conductive ink or conductive paste by having conductive ink puddle over the top of the molding 210 when gap filling the trenches formed in the molding 210. In example embodiments, the trenches may be extended all the way through the semiconductor substrate. In this case, the semiconductor package 220 design rules may be such that the interconnect layers overlying and underlying the regions where the conductive sidewall 212 extends down along the full thickness of the package substrate 202 may have exclusion regions without circuitry to allow the conductive sidewalls 228 to extend through the package substrate 202.

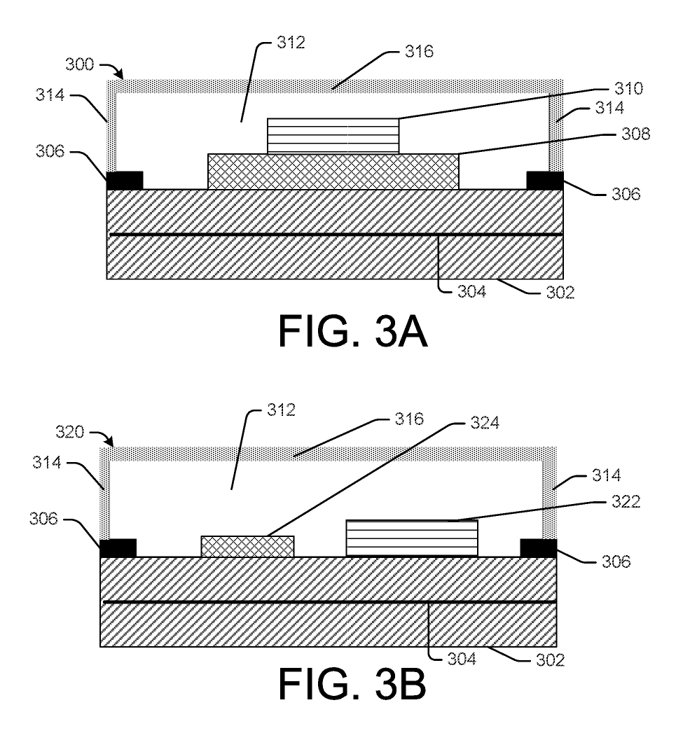

FIGS. 3A and 3B depict simplified cross-sectional schematic diagrams illustrating semiconductor packages 300, 320 with multiple dies 308, 310 provided therein with trenched molding-based EMI shielding 314, 316, in accordance with example embodiments of the disclosure.

FIG. 3A depicts a simplified cross-sectional schematic diagram illustrating a semiconductor package 300 with trenched molding-based EMI shielding having a stacked die configuration. Although two dies (e.g., integrated circuits) 308, 310 are depicted here, it will be appreciated that there may be any suitable number of dies that are stacked within the semiconductor package 300. As shown, the first die 308 may be disposed on the package substrate 302. The package substrate 302 may have a ground build-up layer 304 and surface groundpads or traces 306. The first die 308 may be electrically and mechanically attached to the package substrate by any suitable mechanism including, but not limited to, metal pillars (e.g., copper pillars), flip chip bumps, solder bumps, any type of low-lead or lead-free solder bumps, tin-copper bumps, wire bonds, wedge bonds, C4, ACF, NCF, combinations thereof, or the like.

The second die 310 may be aligned and attached to top of the first die 308. In some example embodiments, the second die 310 may be attached to the first die 308 in a face-down configuration and, in alternative embodiments, the second die 310 may be attached to the first die 308 in a face-up configuration. In the case where the second die 310 is disposed in a face-down configuration, the first die 308 may be in a face-up configuration, and all of the input/output (I/O) connections of the second die 310 may be to the first die 308 in face-to-face connections. In this configuration, I/O signals from the second die 310 may be evacuated via the first die 308, such as via wire bond connections from the first die 308 to the package substrate 302. Alternatively, when the second die 310 is disposed in a face-down configuration, the first die 308 may also be in a face-down configuration and may have through silicon vias (TSVs) to connect the I/O of the second die 310 via the TSVs in the first die 308 to the package substrate 302. In other example embodiments, the both die 308, 310 may be disposed in a face-up configuration and the I/O connections both dies 308, 310 may be made using wire bonding from each die 308, 310 to pads on the package substrate 302 and/or between the second die 310 and the first die 308. In some example embodiments, both TSV-based and wire bond connections may be made for one or both of the dies 308, 310. In yet other example embodiments, one of the dies 308, 310 may be an interposer die for the purposes of making high-density connections, providing greater fan-out ratio, and/or providing relatively more reliable I/O connections.

Continuing with FIG. 3A, the semiconductor package 300 may have molding 312 that encapsulates the dies 308, 310. There may further be a conductive sidewall 314 along the periphery of the semiconductor package 300. The conductive sidewall 314, as described above, may be formed by cured conductive ink and/or conductive paste. The semiconductor package 300 may further include a top conductive portion 316. The top conductive portion 316 may also be constructed of cured conductive ink. The combination of the conductive sidewall 314 and the top conductive portion 316 electrically connected to surface ground pads 306 provide an EMI shielding, in accordance with example embodiments of the disclosure.

FIG. 3B depicts a simplified cross-sectional schematic diagram illustrating a semiconductor package 320 with EMI shielding having a laterally disposed die configuration. Although two dies (e.g., integrated circuits) 322, 324 are depicted here, it will be appreciated that there may be any suitable number of dies that are provided within the semiconductor package 320. As shown, both the first die 322 and the second die 324 may be disposed on the package substrate 302 and may be encapsulated by molding 312. The package substrate 302 may have a ground build-up layer 304 and surface ground pads or traces 306. The first die 322 and the second die 324 may be electrically and mechanically attached to the package substrate 302 by any suitable mechanism including, but not limited to metal pillars (e.g., copper pillars), flip chip bumps, solder bumps, any type of low-lead or lead-free solder bumps, tin-copper bumps, wire bonds, wedge bonds, C4, ACF, NCF, combinations thereof, or the like. It will be appreciated that in some cases both dies 322, 324 may be attached to the substrate using the same mechanism and, in other cases, the dies 322, 324 may be attached using different mechanisms. There may be a conductive sidewall 314 along the periphery of the semiconductor package 320. The conductive sidewall 314, as described above, may be formed by cured conductive ink and/or conductive paste. The semiconductor package 300 may further include a top conductive portion 316. The top conductive portion 316 may also be constructed of cured conductive ink. The combination of the conductive sidewall 314 and the top conductive portion 316 electrically connected to surface ground pads 306 provide an EMI shielding, in accordance with example embodiments of the disclosure.

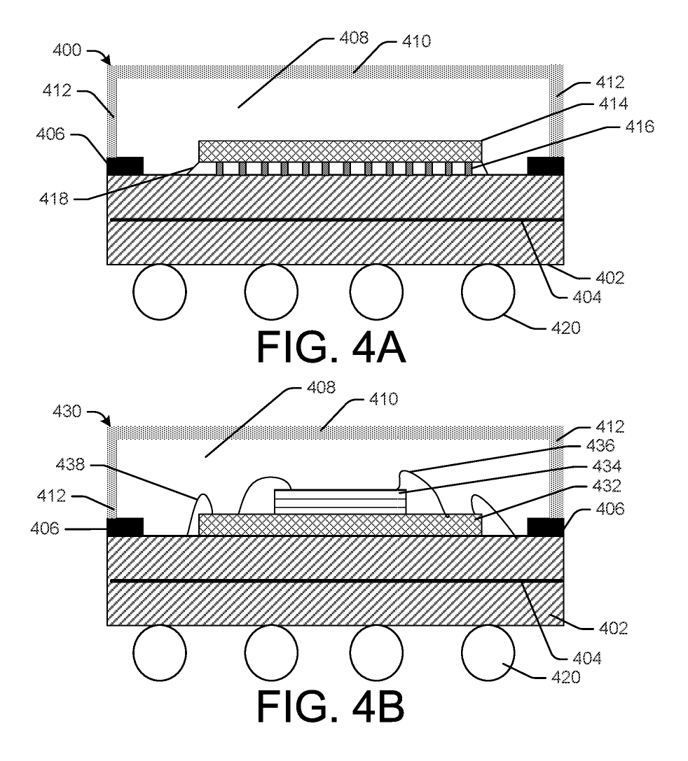

FIGS. 4A and 4B depict simplified cross-sectional schematic diagrams illustrating semiconductor packages 400, 430 having any variety of electrical and mechanical coupling between the die and the semiconductor package having a trenched molding-based EMI shield 400, 430, in accordance with example embodiments of the disclosure.

FIG. 4A depicts a simplified cross-sectional schematic diagram illustrating a semiconductor package 400 having a die 414 that is attached to a package substrate 402 using copper pillars 416. The package substrate 402 may have a ground plane 404 and one or more ground pad contacts 406 provided on the surface of the package substrate 402. The die 414 may be encapsulated by the molding 408, and there may be conductive sidewalls 412 and a conductive top 410 disposed on the molding 408, where the conductive sidewalls 412 and the conductive top 410 are shorted to the surface ground pad contacts 406 to form the EMI shielding, as described herein.

The copper pillars 416 may be of any suitable size. For example, the copper pillars 416 may be approximately in the range of about 10 μm to about 150 μm in width. The die 416 may be aligned and attached to the semiconductor substrate by any suitable mechanisms. For example, a thermosonic process may be used to fuse the copper pillars 416 to corresponding pads on the package substrate using gold/nickel, tin/lead, or any suitable metallurgy. As another example embodiment, a wave soldering process may be used to attach the die 414 to the package substrate 402. In example embodiments, underfill material 418 may be provided around the copper pillars 416, between the die 414 and the package substrate 402. Representative epoxy materials in the underfill 418 may include an amine epoxy, imidizole epoxy, a phenolic epoxy or an anhydride epoxy. Other examples of underfill material include polyimide, benzocyclobutene (BCB), a bismaleimide type underfill, a polybenzoxazine (PBO) underfill, or a polynorbornene underfill. Additionally, the underfill material 418 may include a filler material, such as silica. Underfill material 418 may be introduced by spin coating, extrusion coating or spray coating techniques. In another embodiment, the underfill material 418 includes a standard fabrication passivation material such as an inorganic passivation material (e.g., silicon nitride, silicon oxynitride) or organic passivation material (e.g., polyimide).

The package substrate 402, as described above, may have build-up layers on either side of the substrate core. In some cases, a coreless package substrate 402 may be used. In example embodiments, contacts 420 for package level I/O may be provided on the package substrate 402. The contacts 420 may be any suitable contacts, such as ball grid array (BGA) or other area array contacts 420.

FIG. 4B depicts a simplified cross-sectional schematic diagram illustrating a semiconductor package 430 having two dies 432, 434 that are attached to a package substrate 402 using wire bonds 436, 438, in accordance with example embodiments of the disclosure. The package substrate 402 may have a ground plane 404 and one or more ground pad contacts 406 provided on the surface of the package substrate 402. The dies 432, 434 may be encapsulated by molding 408 and there may be conductive sidewalls 412 and a conductive top 410 disposed on the molding 408, where the conductive sidewalls 414 and the conductive top 412 are shorted to the surface ground pad contacts 406 to form the EMI shielding, as described herein. In example embodiments, contacts 420 for package level I/O may be provided on the package substrate 402. The contacts 420 may be any suitable contacts, such as ball grid array (BGA) or other area array contacts 420.

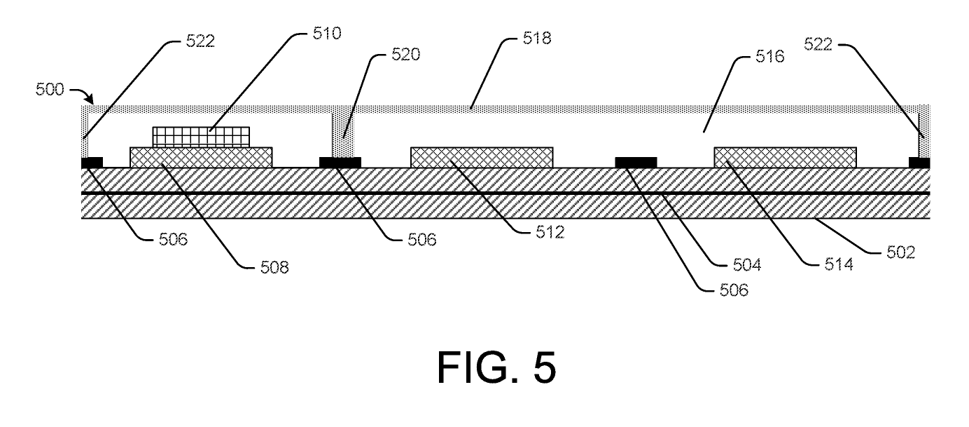

FIG. 5 depicts a simplified cross-sectional schematic diagram illustrating a system in a package (SiP) 500 with trenched molding-based EMI shielding around one or more electronic components 508, 510, 512, 514, in accordance with example embodiments of the disclosure. The SiP 500 may have a package substrate 502 with a ground plane 504 and one or more surface ground pads and/or traces 506. The electronic components 508, 510, 512, 514 may be provided in any suitable configuration and with any suitable electrical connections to the package substrate. For example, electronic components 508 and 510 are disposed in a stacked configuration. The SiP 500 may have molding 516 encapsulating the electronic components 508, 510, 512, 514. The SiP 500 may further have vertical conductive structures 522, 524 disposed in the molding. These vertical conductive structures 522, 524 may be cured conductive ink and/or conductive paste. Thus, upon curing, the vertical conductive structures 522, 524 may have epoxy with conductive particles disposed therein. This conductive epoxy may form vertical portions of an EMI shielding structure. The SiP 500 may further include horizontal conductive material 518 disposed on top of the molding 516. The horizontal conductive material 518 may be formed on to the top surface of the molding 516 by puddling conductive ink over the top surface of the molding 516 and curing that conductive ink. The horizontal conductive material 518 may be electrically connected to the vertical conductive structures 522, 524 and to the surface ground pads and/or traces 506. According to example embodiments of the disclosure, some of the vertical conductive structures 522, 524 may be sidewall conductive structures 522 on the periphery of the semiconductor package and other vertical conductive structures 524 may be internal vertical conductive structures to prevent EMI between the electronic components 508, 510, 512, 514 provided in the same SiP 500. For example, vertical conductive structure 524 may isolate EMI resulting from the combination of electronic components 508, 510 from electronic components 512, 514.

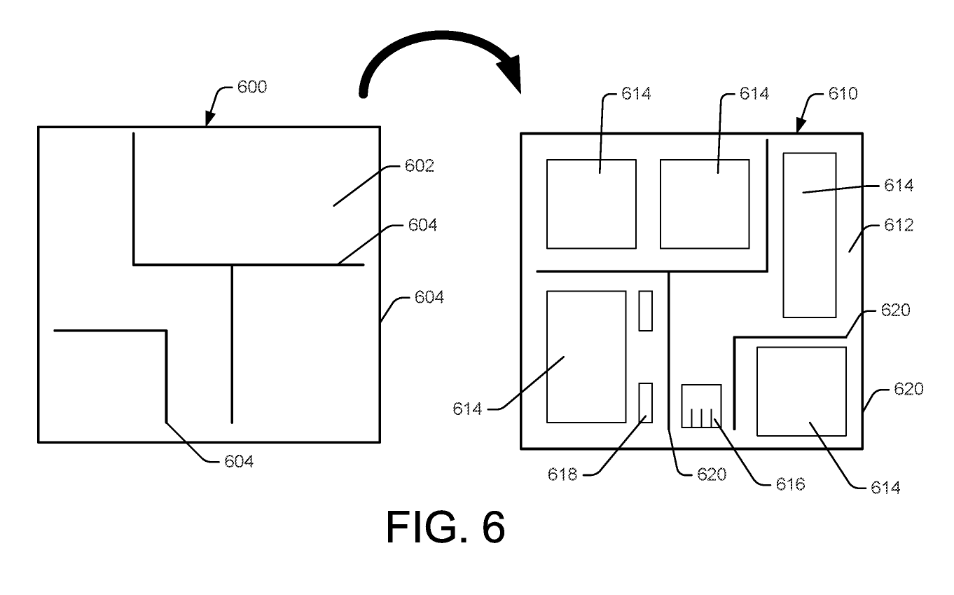

FIG. 6 depicts a simplified schematic diagram illustrating a chase 600 for curing molding epoxy with inserts 604 disposed thereon and a resulting trenching 620 of molding 612 on the surface of a system in a package 610, where the molding epoxy was cured with the chase 600 with the inserts 604, in accordance with example embodiments of the disclosure. The inserts or protrusions 604 may be of any suitable material including, for example, any variety of metal, with or without surface treatment to reduce the stickiness to uncured molding compound. The inserts 604 may protrude from a flat portion 602 of the chase 600. In some example embodiments, the inserts 604 may be brazed and/or welded onto the flat portion 602 of the chase 600. Alternatively, the inserts 604 may be provided in slots provided in the flat portion 602 of the chase.

Once the chase 600 is flipped over to cure epoxy 612 on the package substrate 610, trenches 620 may be formed in the molding 612. It will be appreciated that the molding compound that is formed into the molding 612 upon curing using the chase 600, may encapsulate the various electrical components disposed on the substrate 610, such as various integrated circuits 614, connector 616, and of surface mount devices (SMTs) 618. As shown, trenches 620 in the molding 612 may be formed both along the edges of the package substrate 610 and within the interior portions of the package substrate 620. In example embodiments, the trenches 620 may be aligned over ground pads or ground traces on the package substrate due to an alignment process of the chase 600 to the package substrate prior to the curing process. The alignment process may involve a precise placement apparatus coupled with optical alignment. Fiducial and/or alignment marks on the surface of the package substrate 610 may be used for the purposes of aligning the chase 600 to the package substrate 610.

It will be appreciated that in some example embodiments, the protrusions 604 of the chase 600 may have a finished surface and/or coatings that may reduce the stickiness of the molding compound to the surface of the protrusions 604. For example, in some example embodiments, the protrusions may have a coating of polytetrafluoroethylene (PTFE) deposited thereon. It will further be appreciated that in some example embodiments, the chase 600 may be vibrated during the cure process to reduce any sticking of the molding compound to the inserts 604 of the chase 600. In some example embodiments, the height of the inserts 604 may be substantially similar to the thickness of the molding compound.

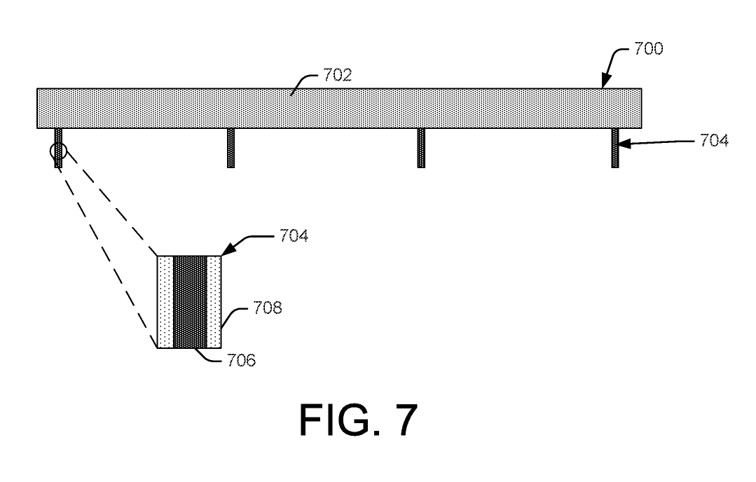

FIG. 7 depicts a simplified cross-sectional schematic diagram of a chase 700 with inserts 704 disposed thereon, in accordance with example embodiments of the disclosure. In example embodiments, the inserts 704 may extend form a flat portion 702 of the chase 700 in substantially a normal direction. The inserts 704 may be brazed on to the flat portion 702 in some example embodiments. In other cases, the inserts 704 may be affixed to the flat portion 702 by any suitable mechanism including, but not limited to, adhesives, mechanical slots, bosses, welding, electrostatic attraction, combinations thereof, or the like. In example embodiments, the inserts 704 may have a central portion 706 and a coating 708 thereon. The coating 708 may be provided to reduce and/or prevent molding compound from sticking to the inserts 704. In some example embodiments, PTFE may be used to coat the inserts 704.

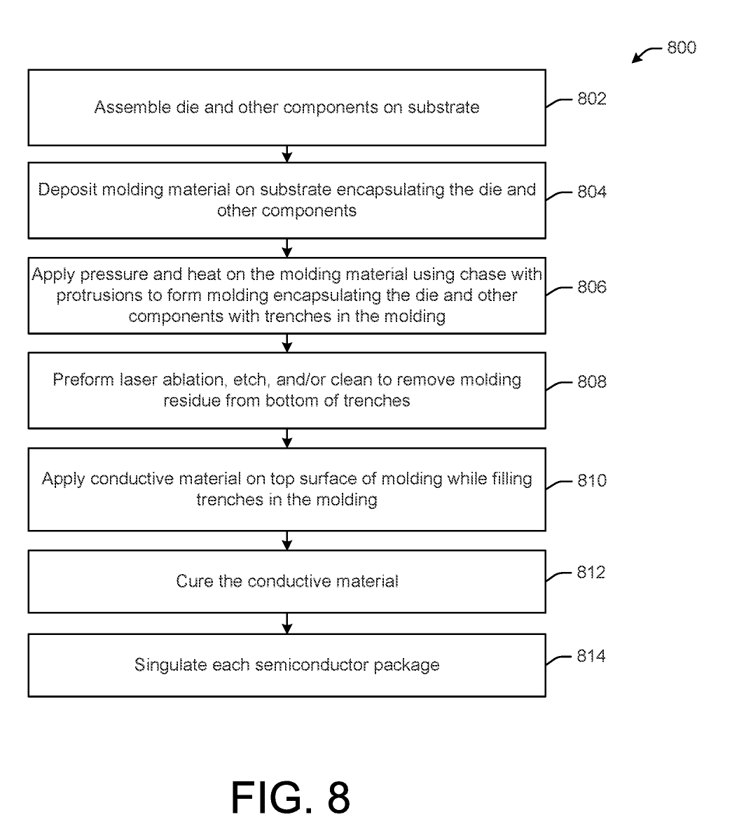

FIG. 8 depicts a flow diagram illustrating an example method 800 for fabricating the semiconductor packages with trenched molding-based EMI structures of FIGS. 1-5, in accordance with example embodiments of the disclosure.

At block 802, a die and other components may be assembled on a substrate. At this point, the substrate may be a substrate panel on which multiple semiconductor packages are fabricated concurrently or nearly concurrently. The substrate (e.g., in panel form) may have build-up layers formed thereon and may be at a stage where the die and/or other structures may be formed thereon. The die may be any suitable electronic device, such as a semiconductor-based electronic device. In example embodiments, the die may be an integrated circuit (IC) with at least one active device (e.g., transistors, diodes, etc.) and/or passive device (e.g., resistors, inductors, capacitors, etc.).

At block 804, molding compound that may encapsulate the die and other components may be deposited on the substrate. As discussed above, in example embodiments, the molding compound may be provided my any suitable mechanism including, but not limited to, being spun-on, sprayed on, dispensed using screen printing, dispensed using screen printing, combinations thereof, or the like. The molding compound may be deposited to a sufficient thickness to encapsulate the die and/or other components on the surface of the substrate. In example embodiments, the molding compound may be a thermosetting compound. In some cases, the molding compound may have one or more filler materials provided therein to engineer various physical, electrical, and/or thermal properties of the molding.

At block 806, pressure and heat may be applied on the molding compound using a chase with protrusions to from molding encapsulating the die and other components with trenches in the molding. It will be appreciated that the trenches formed in the regions of the molding where the protrusions displace molding compound may overlie ground contacts on the package substrate. The application of the chase with protrusions to the molding compound and heating the molding compound may result in the curing process of the molding compound, where the molding compound is cross-linked and/or hardened to form the molding. In some example embodiments, the process of curing may be modified to result in reduced sticking of the molding compound to the protrusions of the chase. For example, relatively small lateral movements (e.g., vibrating along the plane of the package substrate), may be used to reduce the amount of sticking to the protrusions. The cure temperature of the molding compound may be approximately in the range of about 100° C. to about 250° C. In some example embodiments, the cure temperature may be approximately in the range of about 150° C. to about 200° C.

At block 808, laser ablation, etch, and/or clean process(es) may be performed to remove molding residue at the bottom of the trenches. Although the trenches are formed in-situ during the curing process of block 806, the trenches may not always reliably open up to the ground pads and/or traces below. As a result, any variety of process(es) may be employed for the purposes of removing the residue at the bottom of the trenches. The trenches may be cleaned by any variety of mechanisms, such as laser ablation, wet etching, dry etching, or any combination thereof. In some example embodiments, the process used to clean the molding residue at the bottom of the trenches may also result in a lateral etch (e.g., widening) of the trenches. In these embodiments, the residue cleaning processes may be tuned for relatively greater directionality in etching in a vertical direction with greater rate than in the lateral direction.

At block 810, conductive material may be applied to the top surface of the molding. The trenches in the molding formed by the processes of blocks 806 and 808 may be filled with the conductive material. Furthermore the, the conductive material may be puddled over the top of the molding to form the top horizontal portion of the EMI shielding. In example embodiments, the conductive material may be conductive ink and/or conductive paste. The conductive ink or conductive paste may be an epoxy material with conductive particles provided (e.g., suspended) therein. The conductive ink and/or conductive paste may include other materials therein, such as reducing agents, fillers, etc. In example embodiments, the conductive ink and/or conductive paste may be deposited by a spin-on, spray-on, squeegee, and/or screen printing process. In some cases (e.g., screen printing), the deposition of the conductive ink and/or conductive paste may be in and/or near the molding trenches that are to be filled. In some cases, the conductive ink and/or conductive paste may be a thixotropic material and, thus, may preferentially flow into the trenches and then stage in a relatively more rigid form. In yet further example embodiments, a first relatively less viscous and relatively more gap filling conductive ink may be disposed to fill the trenches and then a more viscous conductive ink may be deposited thereon to form the top portion of the EMI shielding.

At block 812, the conductive material may be cured. The cure temperature may be approximately in the range of about 100° C. to about 250° C. In some example embodiments, the cure temperature may be approximately in the range of about 150° C. to about 175° C.

At block 814, each of the packages may be singulated. The singulation may be performed by any suitable mechanism, such as by laser ablation or saw cut. If laser ablation is used, then the cut width may be smaller than the width of the filled trenches. In this way, when the semiconductor packages are singulated from each other by cutting the semiconductor substrate panel, the conductive material (e.g., cured conductive ink, cured conductive paste, etc.) may remain on both sides of the cut and provide a conductive sidewall of an EMI shield on adjacent semiconductor packages, in accordance with example embodiments of the disclosure.

It should be noted that the method 800, as disclosed herein, may enable a relatively reliable mechanism for fabricating the electromagnetic interference shield of the semiconductor package. The use of conductive ink for the EMI shield may provide for a relatively more cost-effective mechanism for the fabrication of the EMI shield compared to other methods, such as physical vapor deposition (PVD) of conductive material. Furthermore, the formation of the trenches in the molding in-situ, during the curing process of the molding compound, may result in a relatively efficient, cost effective, and relatively reliable mechanism for forming the trenches in which the vertical portions of the EMI shield is formed. Additionally, the formation of trenches within the molding and filling those trenches with relatively more compliant material may provide for stress relief and other mechanisms for improved reliability of the semiconductor package compared to other methods of forming EMI shields.

It should be noted, that the method 800 may be modified in various ways in accordance with certain embodiments of the disclosure. For example, one or more operations of the method 800 may be eliminated or executed out of order in other embodiments of the disclosure. Additionally, other operations may be added to the method 800 in accordance with other embodiments of the disclosure.

It will be appreciated that the apparatus described herein may be any suitable type of microelectronics packaging and configurations thereof, including, for example, system in a package (SiP), system on a package (SOP), package on package (PoP), interposer package, 3D stacked package, etc. In fact, any suitable type of microelectronic components may be provided in the semiconductor packages with EMI shielding, as described herein. For example, microcontrollers, microprocessors, baseband processors, digital signal processors, memory dies, field gate arrays, memory dies, logic gate dies, passive component dies, MEMSs, surface mount devices, application specific integrated circuits, baseband processors, amplifiers, filters, combinations thereof, or the like may be packaged in the semiconductor packages with EMI shielding, as disclosed herein. The semiconductor packages with EMI shielding, as disclosed herein, may be provided in any variety of electronic devices including, consumer, industrial, military, communications, infrastructural, and/or other electronic devices.

The semiconductor package with EMI shielding, as described herein, may be used to house one or more processors. The one or more processors may include, without limitation, a central processing unit (CPU), a digital signal processor(s) (DSP), a reduced instruction set computer (RISC), a complex instruction set computer (CISC), a microprocessor, a microcontroller, a field programmable gate array (FPGA), or any combination thereof. The processors may also include one or more application specific integrated circuits (ASICs) or application specific standard products (ASSPs) for handling specific data processing functions or tasks. In certain embodiments, the processors may be based on an Intel® Architecture system, and the one or more processors and any chipsets included in an electronic device may be from a family of Intel® processors and chipsets, such as the Intel® Atom® processor(s) family or Intel-64 processors (e.g., Sandy Bridge®, Ivy Bridge®, Haswell®, Broadwell®, Skylake®, etc.).

Additionally or alternatively, the semiconductor package with EMI shielding, as described herein, may be used to house one or more memory chips. The memory may include one or more volatile and/or non-volatile memory devices including, but not limited to, magnetic storage devices, read-only memory (ROM), random access memory (RAM), dynamic RAM (DRAM), static RAM (SRAM), synchronous dynamic RAM (SDRAM), double data rate (DDR) SDRAM (DDR-SDRAM), RAM-BUS DRAM (RDRAM), flash memory devices, electrically erasable programmable read-only memory (EEPROM), non-volatile RAM (NVRAM), universal serial bus (USB) removable memory, or combinations thereof.

In example embodiments, the electronic device in which the semiconductor package with EMI shielding is provided may be a computing device. Such a computing device may house one or more boards on which the semiconductor package with EMI shielding may be disposed. The board may include a number of components, including but not limited to a processor and/or at least one communication chip. The processor may be physically and electrically connected to a board through, for example, electrical connections of the semiconductor package with EMI shielding. The computing device may further include a plurality of communication chips. For instance, a first communication chip may be dedicated to shorter range wireless communications such as Wi-Fi and Bluetooth, and a second communication chip may be dedicated to longer range wireless communications such as GPS, EDGE, GPRS, CDMA, WiMAX, LTE, EV-DO, and others. In various example embodiments, the computing device may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, a digital video recorder, combinations thereof, or the like. In further example embodiments, the computing device may be any other electronic device that processes data.

Various features, aspects, and embodiments have been described herein. The features, aspects, and embodiments are susceptible to combination with one another as well as to variation and modification, as will be understood by those having skill in the art. The present disclosure should, therefore, be considered to encompass such combinations, variations, and modifications.

The terms and expressions which have been employed herein are used as terms of description and not of limitation, and there is no intention, in the use of such terms and expressions, of excluding any equivalents of the features shown and described (or portions thereof), and it is recognized that various modifications are possible within the scope of the claims. Other modifications, variations, and alternatives are also possible. Accordingly, the claims are intended to cover all such equivalents.

While the disclosure includes various embodiments, including at least a best mode, it is to be understood that many alternatives, modifications, and variations will be apparent to those skilled in the art in light of the foregoing description. Accordingly, the disclosure is intended to embrace all such alternatives, modifications, and variations, which fall within the scope of the included claims. All matters disclosed herein or shown in the accompanying drawings are to be interpreted in an illustrative and non-limiting sense.

This written description uses examples to disclose certain embodiments of the disclosure, including the best mode, and also to enable any person skilled in the art to practice certain embodiments of the disclosure, including making and using any apparatus, devices, or systems and performing any incorporated methods and processes. The patentable scope of certain embodiments of the invention is defined in the claims, and may include other examples that occur to those skilled in the art. Such other examples are intended to be within the scope of the claims if they have structural elements that do not differ from the literal language of the claims, or if they include equivalent structural elements with insubstantial differences from the literal language of the claims.

According to example embodiments of the disclosure, there may be a microelectronics package, comprising: a substrate having a top substrate surface and a substrate outer periphery, the top substrate surface having an electronic component mounted thereon and the top substrate surface having a conductive trace, the conductive trace disposed along at least a portion of the substrate outer periphery; a molding compound provided over the top substrate surface, having a bottom molding surface, a top molding surface, and a molding sidewall substantially overlying the substrate outer periphery; and epoxy provided on the molding sidewall and overlying the top molding surface, wherein the epoxy includes conductive particles, and wherein the epoxy overlying the top molding surface and the epoxy on the molding sidewall are electrically coupled. In example embodiments, the epoxy is further electrically coupled to the conductive trace. In further example embodiments, the conductive trace is electrically connected to at least one of: (i) ground, (ii) a direct current (DC) voltage, or (iii) a power line voltage of the microelectronics package. In still further example embodiments, the substrate includes a core layer and at least one build-up layer having metal lines, wherein the metal lines include at least the conductive trace. In yet further example embodiments, the molding compound comprises a thermosetting epoxy compound.

According to example embodiments of the disclosure, the molding includes a conductive structure extending from the bottom molding surface to the top molding surface, and electrically connected to the epoxy provided overlying the top molding surface. In further example embodiments, the epoxy comprises at least one of: (i) cured conductive ink, (ii) cured conductive paste, or (iii) silver nanoparticles. In still further example embodiments, the electronic component is a first electronic component, and wherein the microelectronics package further comprises: a second electronic component; and a conductive structure electrically connected to the conductive trace and the epoxy provided on the top molding surface, the conductive structure disposed between the first electronic component and the second electronic component in a trench formed in the molding extending from the bottom molding surface to the top molding surface. In yet further example embodiments, the microelectronics package further includes a plurality of package-to-board electrical connections disposed on a bottom substrate surface of the substrate.

According to example embodiments of the disclosure, there may be a method comprising: providing a package substrate panel with a panel top surface; electrically attaching a first electronic component and a second electronic component to the panel top surface; depositing molding compound on the panel top surface, wherein the molding compound encapsulates the first electronic component and the second electronic component; applying a chase to a top surface of the molding compound to cure the molding compound to form a molding, the chase having a flat portion and one or more protrusions extending from the flat portion in a substantially normal direction to the flat portion, the molding having a bottom molding surface contacting the panel top surface and a top molding surface, wherein the molding includes one or more trenches corresponding to the protrusions of the chase; and filling the one or more trenches with epoxy, wherein the epoxy comprises conductive particles. In example embodiments, the method further comprises singulating a portion of the package substrate panel through a first of the one or more filled trenches and an underlying portion of the package substrate panel. In further example embodiments, singulating the portion of the package substrate panel through the first of the one or more filled trenches and the underlying portion of the package substrate panel comprises: cutting through the filled trench and the underlying portion of the package substrate panel, the cut having a cut width, wherein the cut width is less than a width of the first of the plurality of filled trenches. In still further example embodiments, providing the package substrate panel comprises providing a package core with at least one build-up layer formed on the package core. According to embodiments of the disclosure, the package substrate panel includes an electrical trace on the panel top surface, and wherein curing the molding compound comprises removing molding from at least a part of a surface of the electrical trace.

According to example embodiments of the disclosure, the first of the plurality of filled trenches is disposed between the first electronic component and the second electronic component, and wherein the portion of the package substrate panel includes the first electronic component and not the second electronic component. In further example embodiments, the portion of the package substrate panel includes a third electronic component, and wherein there is a second of the plurality of filled electrical trenches disposed between the first electronic component and the third electronic component. According to example embodiments, attaching the first electronic component to the panel top surface comprises bonding copper pillars of the first electronic component onto one or more pads on the panel top surface. In still further example embodiments, the method further comprises removing reside at a bottom of the one or more trenches using at least one of: (i) a wet etch, (ii) a dry etch, or (iii) laser ablation. In yet further example embodiments, the method further comprises forming a top conductive layer with the epoxy. According to some example embodiments, depositing molding compound on the panel top surface comprises depositing a quantity of the molding compound to fill the one or more trenches and form the top conductive layer.

1. A microelectronics package, comprising:
a substrate having a top substrate surface and a substrate outer periphery, the top substrate surface having an electronic component mounted thereon and the top substrate surface having a conductive trace, the conductive trace disposed along at least a portion of the substrate outer periphery;
a molding compound provided over the top substrate surface, having a bottom molding surface, a top molding surface, and a molding sidewall substantially overlying the substrate outer periphery; and
epoxy provided on the molding sidewall and overlying the top molding surface, wherein the epoxy includes conductive particles, and wherein the epoxy overlying the top molding surface and the epoxy on the molding sidewall are electrically coupled.

2. The microelectronics package of claim 1, wherein the epoxy is further electrically coupled to the conductive trace.

3. The microelectronics package of claim 2, wherein the conductive trace is electrically connected to at least one of: (i) ground, (ii) a direct current (DC) voltage, or (iii) a power line voltage of the microelectronics package.

4. The microelectronics package of claim 1, wherein the substrate includes a core layer and at least one build-up layer having metal lines, wherein the metal lines include at least the conductive trace.

5. The microelectronics package of claim 1, wherein the molding compound comprises a thermosetting epoxy compound.

6. The microelectronics package of claim 1, wherein the molding includes a conductive structure extending from the bottom molding surface to the top molding surface, and electrically connected to the epoxy provided overlying the top molding surface.

7. The microelectronics package of claim 1, wherein the epoxy comprises at least one of: (i) cured conductive ink, (ii) cured conductive paste, or (iii) silver nanoparticles.

8. The microelectronics package of claim 1, wherein the electronic component is a first electronic component, and wherein the microelectronics package further comprises:
a second electronic component; and
a conductive structure electrically connected to the conductive trace and the epoxy provided on the top molding surface, the conductive structure disposed between the first electronic component and the second electronic component in a trench formed in the molding extending from the bottom molding surface to the top molding surface.

9. The microelectronics package of claim 1, further comprising a plurality of package-to-board electrical connections disposed on a bottom substrate surface of the substrate.

10. A method, comprising:
providing a package substrate panel with a panel top surface;
electrically attaching a first electronic component and a second electronic component to the panel top surface;
depositing molding compound on the panel top surface, wherein the molding compound encapsulates the first electronic component and the second electronic component;
applying a chase to a top surface of the molding compound to cure the molding compound to form a molding, the chase having a flat portion and one or more protrusions extending from the flat portion in a substantially normal direction to the flat portion, the molding having a bottom molding surface contacting the panel top surface and a top molding surface, wherein the molding includes one or more trenches corresponding to the protrusions of the chase; and
filling the one or more trenches with epoxy, wherein the epoxy comprises conductive particles.

11. The method of claim 10, further comprising singulating a portion of the package substrate panel through a first of the one or more filled trenches and an underlying portion of the package substrate panel.

12. The method of claim 11, wherein singulating the portion of the package substrate panel through the first of the one or more filled trenches and the underlying portion of the package substrate panel comprises:
cutting through the filled trench and the underlying portion of the package substrate panel, the cut having a cut width, wherein the cut width is less than a width of the first of the plurality of filled trenches.

13. The method of claim 10, wherein providing the package substrate panel comprises providing a package core with at least one build-up layer formed on the package core.

14. The method of claim 10, wherein the package substrate panel includes an electrical trace on the panel top surface, and wherein curing the molding compound comprises removing molding from at least a part of a surface of the electrical trace.

15. The method of claim 10, wherein the first of the plurality of filled trenches is disposed between the first electronic component and the second electronic component, and wherein the portion of the package substrate panel includes the first electronic component and not the second electronic component.

16. The method of claim 15, wherein the portion of the package substrate panel includes a third electronic component, and wherein there is a second of the plurality of filled electrical trenches disposed between the first electronic component and the third electronic component.

17. The method of claim 10, wherein attaching the first electronic component to the panel top surface comprises bonding copper pillars of the first electronic component onto one or more pads on the panel top surface.

18. The method of claim 10, further comprising removing reside at a bottom of the one or more trenches using at least one of: (i) a wet etch, (ii) a dry etch, or (iii) laser ablation.

19. The method of claim 10, further comprises forming a top conductive layer with the epoxy.

20. The method of claim 19, wherein depositing molding compound on the panel top surface comprises depositing a quantity of the molding compound to fill the one or more trenches and form the top conductive layer.
